(19) United States
(12) Patent Application Publication
(10) Pub. No.: US 2025/0110159 A1
(43) Pub. Date: Apr. 3, 2025

(54) CURRENT SENSOR

(71) Applicant: Asahi Kasei Microdevices Corporation, Tokyo (JP)

(72) Inventor: Masato INOUE, Tokyo (JP)

(21) Appl. No.: 18/898,680

(22) Filed: Sep. 27, 2024

(30) Foreign Application Priority Data
Sep. 29, 2023 (JP) 2023-169211
Aug. 30, 2024 (JP) 2024-148144

(51) Int. Cl. G01R 19/00; G01R 33/09

(52) U.S. Cl. CPC G01R 19/0092; G01R 33/09

(57) ABSTRACT

A magnetic sensor 60 includes a substrate 61; a plurality of magneto-resistive elements 51 disposed on the substrate, wherein a part of the plurality of magneto-resistive elements is assembled into a Wheatstone bridge circuit to form a magneto-electric conversion unit 62a and another part is assembled into a Wheatstone bridge circuit to form a magneto-electric conversion unit 62b; and a plurality of electrode pads 63_{#1} to 63_{#6} disposed on the substrate including a first and a second electrode pad connected to the drive terminal VDD and the ground terminal GND of the magneto-electric conversion units 62a, 62b, respectively, a third and a fourth electrode pad connected to two output terminals Npa1, Npa2 of the magneto-electric conversion unit 62a, respectively, and a fifth and a sixth electrode pad connected to the two output terminals Npb1, Npb2 of the magneto-electric conversion unit 62b, respectively.

The contents of the following patent application(s) are incorporated herein by reference:
NO. 2023-169211 filed in JP on Sep. 29, 2023
No. 2024-148144 filed in JP on Aug. 30, 2024

### BACKGROUND

### 1. Technical Field

The present invention relates to a current sensor.

### 2. Related Art

A magnetic sensor is known that includes a Wheatstone bridge circuit constituted of four resistive sides each including a magneto-resistive element (TMR) and detects a magnetic field intensity by inputting a drive voltage from a pair of power supply terminals and obtaining a differential voltage from a pair of output terminals and a current sensor is known that detects, by using the magnetic sensor, the amount of current by measuring the magnetic field intensity around a conductor through which a to-be-measured current flows (see Patent Documents 1 and 2). The current sensor includes a substrate that supports the magnetic sensor, inputs the drive voltage to the power supply terminal of the magnetic sensor via a plurality of electrode pads provided on the substrate, and outputs a differential voltage from the output terminal. Herein, when the current sensor is used in a moisture absorption state, a voltage is applied between the electrode pads, resulting in the occurrence of the migration of the electrode pad, which possibly reduces the detection sensitivity. Therefore, in Patent Document 3, the migration is suppressed by forming an electrode pad with multiple layer arrangement by using silver containing any of an oxygen compound, nitrogen compound, or oxygen-nitrogen compound. However, because a special material that is typically not used as an electrode material is used, there is a concern about a process restriction and an increase in cost.

Patent Document 1 International Publication No. 2015/107949

Patent Document 2 Specification of U.S. Patent Application Publication No. 2020/0018780

Patent Document 3 Japanese Patent Application Publication No. 2005-033197

### BRIEF DESCRIPTION OF THE DRAWINGS

FIG. 1A illustrates an internal configuration of a current sensor according to the present embodiment in a top view.

FIG. 1B illustrates the internal configuration of the current sensor according to the present embodiment in a side view.

FIG. 2A illustrates an example of an arrangement and substrate layout of a magnetic sensor that detects a horizontal magnetic field.

FIG. 2B illustrates a configuration of a magneto-resistive element in a side view.

FIG. 3 illustrates a circuit configuration of the magnetic sensor (first and second magneto-electric conversion units) and a magnetic field detection direction of the magneto-resistive element.

FIG. 4A illustrates an example (a comparative example, samples 1 and 2) of a combination of a connection between an electrode pad and six terminals of the magnetic sensor.

FIG. 4B illustrates an example (sample 3 to 5) of a combination of a connection between an electrode pad and the six terminals of the magnetic sensor.

FIG. 5 illustrates an example of laying the wiring in sample 5 of a combination of a connection between the electrode pad and the six terminals of the magnetic sensor.

FIG. 6 illustrates another example of laying the wiring in sample 5 of a combination of a connection between the electrode pad and the six terminals of the magnetic sensor.

FIG. 7A illustrates the state of a lead frame forming process in a manufacturing flow of the current sensor.

FIG. 7B illustrates the state of a magnetic sensor installing process in the manufacturing flow of the current sensor.

FIG. 7C illustrates the state of a wire bonding process in the manufacturing flow of the current sensor.

FIG. 7D illustrates the state of the molding process in the manufacturing flow of the current sensor.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

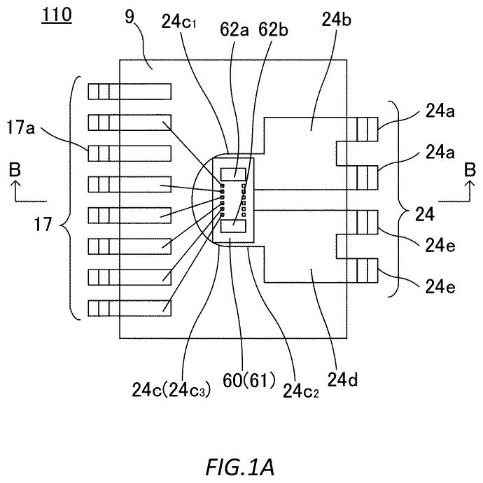

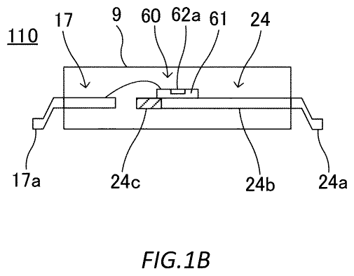

FIG. 1A and FIG. 1B illustrate the internal configuration of the current sensor 110 according to the present embodiment in the top view and the side view, respectively, where the package 9 is omitted. Herein, FIG. 1B illustrates a cross-sectional structure of the current sensor 110 with respect to a reference line BB in FIG. 1A. It should be noted that an up-and-down direction in FIG. 1A is referred to as a longitudinal direction, a left-and-right direction in FIG. 1A and FIG. 1B is referred to as a lateral direction, and an up-and-down direction in FIG. 1B is referred to as a height direction. The current sensor 110 is a sensor that measures the amount of current by detecting, by using the magnetic sensor 60, the magnetic field generated around the conductor 24 through which the to-be-measured current flows and, in particular, can suppress the migration of the plurality of electrode pads 63_{#1} to 63_{#6} and the plurality of dummy pads 64_{#1} to 64_{#6} of the magnetic sensor 60. The current sensor 110 includes a package 9, a plurality of device terminals 17, the conductor 24, and the magnetic sensor 60.

The package 9 is a member that protects each portion constituting the current sensor 110 by encapsulates it inside, except for the plurality of device terminals 17 and each terminal portion of the conductor 24. The package 9 is formed of an encapsulating resin with a good insulating property such as epoxy, for example, that is shaped into a flat cuboid by molding.

The plurality of device terminals 17 (one example of the plurality of output terminals) are secondary conductors that are each connected to the electrode pads 63_{#1} to 63_{#6} of the magnetic sensor 60 described below and output, to an external device, the detection result of the to-be-measured current (that is, the magnetic field intensity) output from the magnetic sensor 60. In the present example, as one example, eight device terminals 17 are arranged at regular intervals on the left side of the package 9 with their longitudinal sides being oriented in the lateral direction. The device terminal 17 is made of metal and formed into a rectangular-shaped board with the end being bent downward by a bending process, with the tip further being bent in the horizontal direction, which forms the terminal portion 17a on each end.

The conductor 24 is a primary conductor that forms a current path in which the

to-be-measured current is flowing. In the present embodiment, the conductor 24 has an approximately U-shape that enters into the package 9 from a current terminal 24a provided on one side (that is, the upper side of FIG. 1A) of the right side of the package 9 and returns to the right side by passing through an interior of the package 9, and leading to a current terminal 24e provided on the other side (that is, the lower side of FIG. 1A) of the right side. The conductor 24 is formed of a conductive metal. The conductor 24 includes current terminals (also simply referred to as a terminal portion) 24a, 24e, barrel portions 24b, 24d, and a curved portion 24c.

Each of the terminal portions 24a, 24e forms a terminal for inputting a current, by protruding from the right side of the package 9, bending their end portion downward by a bending process, and further bending the tip to be positioned horizontally.

The barrel portions 24b, 24d are portions connecting the terminal portions 24a, 24e to the curved portion 24c. The barrel portions 24b, 24d are formed into a rectangular shape as one example, are connected to the two terminal portions 24a, 24e on the right side, which are separated, and are connected to the two arms 24c₁, 24c₂ of the curved portion 24c on the left side.

The curved portion 24c has the two arms 24c₁, 24c₂, and a joining portion 24c₃ that physically joins these two arms 24c₁, 24c₂. The two arms 24c₁, 24c₂ may extend on the same side with respect to the joining portion 24c₃. Herein, the direction in which the width of the arm 24c₁ expands (identical to the longitudinal direction in FIG. 1A) is also referred to as a width direction and the direction in which the arm 24c₁ extends relative to the joining portion 24c₃ is also referred to as an extension direction (identical to the lateral direction in FIG. 1A). In other words, the width direction and the extension direction intersect. The two arms 24c₁, 24c₂ have widths in the longitudinal direction that are smaller than those of the barrel portions 24b, 24d. In the curved portion 24c, the joining portion 24c₃ curves in an approximately arc shape, from both ends of which the two arms 24c₁, 24c₂, separated from each other in the width direction, extend in the lateral direction. It should be noted that the curved portion 24c may bend to have a rectangular U-shape. In the curved portion 24c, the to-be-measured current is input into one arm among the two arms 24c₁, 24c₂ and the to-be-measured current is output from the other arm via the joining portion 24c₃.

The conductor 24 has the two arms 24c₁, 24c₂, included in the curved portion 24c, arranged at the center of the package 9, has the tips of the terminal portions 24a, 24e protruding from the right side of the package 9, and is encapsulated within the package 9.

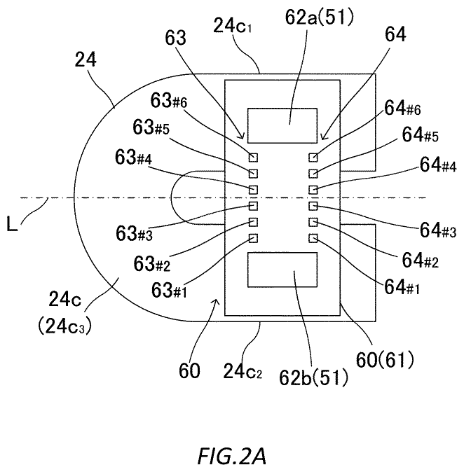

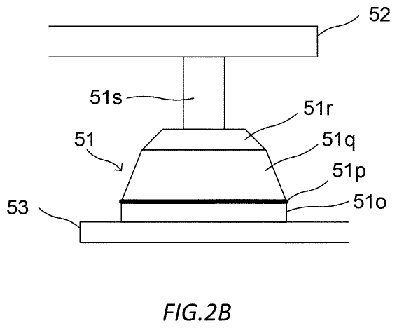

FIG. 2A illustrates a positional example of an arrangement and substrate layout of the magnetic sensor 60. The magnetic sensor 60 is a sensor that detects the magnetic field generated by the to-be-measured current flowing through the conductor 24. As an example, the magnetic sensor 60 is configured to detect the magnetic field in the longitudinal direction generated around the conductor 24 (one example of the magnetic field in the horizontal direction) as one example and includes a substrate 61, a plurality of magneto-resistive elements 51, a plurality of electrode pads 63_{#1} to 63_{#6} and a plurality of dummy pads 64_{#1} to 64_{#6}.

The substrate 61 is a board-shaped member that supports two magneto-electric

conversion units 62a, 62b. The substrate 61 is formed of silicon (Si), for example, and a plurality of wirings (not shown in FIG. 2A) are laid on the upper surface.

The plurality of magneto-resistive elements 51 are elements with the resistance value varying depending on the application of the magnetic field and are each disposed on one side and the other side of the substrate 61 in the longitudinal direction, forming the two magneto-electric conversion units 62a, 62b. The magneto-electric conversion unit 62a (one example of the first sensor) is formed by assembling a part of the plurality of magneto-resistive elements 51 (that is, the magneto-resistive element 51 disposed on the upper side in FIG. 2A) into a Wheatstone bridge circuit. The magneto-electric conversion unit 62b (one example of the second sensor) is formed by assembling another part of the plurality of magneto-resistive elements 51 (that is, the magneto-resistive element 51 disposed on the lower side in FIG. 2A) into a Wheatstone bridge circuit. It should be noted that, as a magneto-resistive element, for example, a tunneling magneto-resistive element or a huge magneto-resistive element can be employed.

FIG. 2B illustrates the configuration of the magneto-resistive element 51 in the side view. The magneto-resistive element 51 is an element with a resistance value varying depending on application of a magnetic field, and has a fixed layer 51o, a tunnel layer 51p, a free layer 51q, and a cap layer 51r. The fixed layer 51o is a magnetic film whose direction of magnetization is fixed. The fixed layer 51o is magnetized such that its magnetization is oriented in a single-axial direction in a plane on which the magnetic film spreads (also referred to as a magneto-sensitive surface) or in a direction perpendicular to the magneto-sensitive surface. The direction of magnetization of the fixed layer 51ₒ defines a magnetic field detection direction of the magneto-resistive element 51. The tunnel layer 51p is, for example, a non-magnetic insulating film with a thickness of several nanometers. The free layer 51q is a magnetic film whose direction of magnetization changes depending on an external magnetic field. It should be noted that, as the material of the magnetic film, an alloy including, for example, at least one of Co, Fe, B, Ni, or Si and more specifically cobalt iron (CoFe), cobalt iron boron (CoFeB), or nickel iron (NiFe) can be used. The fixed layer 51o, the tunnel layer 51p, and the free layer 51q are stacked to constitute a stacked body. Here, a current flows in the element in a stacked direction as a result of electrons moving from the fixed layer 51o to the free layer 51q or from the free layer 51q to the fixed layer 51o by tunneling through the tunnel layer 51p. The cap layer 51r is a member covering the stack from above and can be made of an alloy including at least one of, for example, Ta, Ru, Pt, Mn, Ir, Mg, Cu, Fe, Ni, Cr, Fe, Co, or Al, more specifically, platinum manganese (PtMn) or iridium manganese (IrMn). It should be noted that a region around the magneto-resistive element 51 is covered with an insulator (not shown), for example, silicon dioxide (SiO2), silicon nitride (SiN), or the like.

When the external magnetic field is applied to the magneto-resistive element 51, due to

a magneto-resistive effect (MR effect), the direction of magnetization of the free layer 51q changes depending on a direction and intensity of the magnetic field, that is, the direction of magnetization of the free layer 51q changes with respect to the direction of magnetization of the fixed layer 51o, so that the resistance value between the fixed layer 51o and the free layer 51q varies. Especially, when the direction of magnetization of the free layer 51q is the same as the direction of magnetization of the fixed layer 51o (the magnetizations of the two layers are parallel), the resistance value is small, and when the direction of magnetization of the free layer 51q is opposite to the direction of magnetization of the fixed layer 51o (the magnetizations of the two layers are antiparallel), the resistance value is high.

It should be noted that connecting a plurality of magneto-resistive elements 51 connected in series can improve a DC voltage resistance. Herein, by connecting the electrode piece 52 to the cap layer 51r via the electrode rod 51s and connecting the electrode piece 53 to the lower surface of the fixed layer 51o, the magneto-resistive element 51 can be connected to another magneto-resistive element 51 via these electrode pieces 52, 53. In other words, the plurality of magneto-resistive elements 51 can be arranged in a plane. In addition, the plurality of magneto-resistive element 51 can be arranged three-dimensionally by connecting the cap layer 51r of the magneto-resistive element 51 to the fixed layer 51o of another magneto-resistive element 51 via the electrode rod 51s.

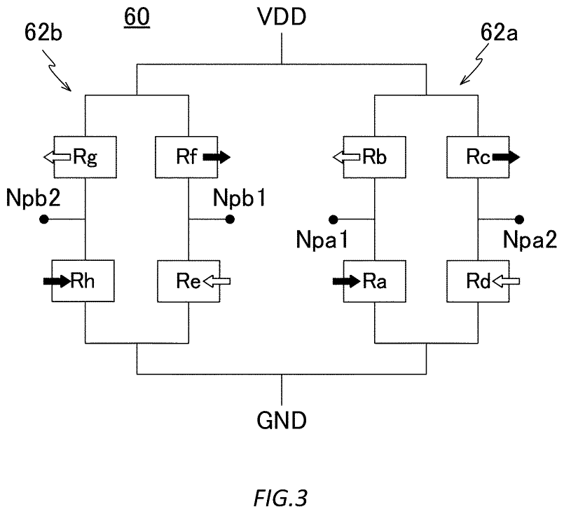

FIG. 3 illustrates the circuit configuration of the magnetic sensor 60 (two magneto-electric conversion units 62a, 62b) and the magnetic field detection directions of the resistive sides Ra to Rh (the magneto-resistive element 51 included in each of them). The magnetic sensor 60 includes two magneto-electric conversion units 62a, 62b connected in parallel between each drive terminal VDD and ground terminal GND.

The magneto-electric conversion unit 62a includes four resistive sides Ra to Rd forming the Wheatstone bridge circuit. Each of the resistive sides Ra to Rd is formed of the above-described plurality of magneto-resistive elements 51 connected in series. Herein, in the four resistive sides Ra to Rd, the resistive side Ra and the resistive side Rb are connected in series to form the output terminal Npa1 between them, the resistive side Rc and the resistive side Rd are connected in series to form the output terminal Npa2 between them, the resistive side Ra and the resistive side Rb and the resistive side Rc and the resistive side Rd are connected in parallel to form a drive terminal VDD between the resistive side Rb and the resistive side Rc as well as to form the ground terminal GND between the resistive side Ra and the resistive side Rd.

It should be noted that, in the current sensor 110 according to the present embodiment, the magnetic field detection direction from the resistive side Ra to the resistive side Rd (that is, the magnetic sensing direction) is a single-axial direction parallel to the upper surface of the conductor 24 (the longitudinal direction in FIG. 1A). The magnetic field detection directions of the resistive side Ra and the resistive side Rc (the magneto-resistive elements 51 forming each of them) are identical to each other (indicated with filled arrows in FIG. 3) and are upward (or downward) in the longitudinal direction in FIG. 1A in the present example. The magnetic field detection directions of the resistive side Rb and the resistive side Rd (the magneto-resistive elements 51 forming each of them) are also identical to each other (indicated with hollow arrows in FIG. 3) and are downward (or upward) in the longitudinal direction in FIG. 1A in the present example. The magnetic field detection direction of the resistive side Ra and the resistive side Rc is opposite to the magnetic field detection direction of the resistive side Rb and the resistive side Rd.

The magneto-electric conversion unit 62a is arranged on the arm 24c₁ of the conductor 24. When the to-be-measured current flows through the conductor 24 and a magnetic field is generated around the conductor 24, a magnetic field in the longitudinal direction is applied to the resistive sides Ra to Rd (the magneto-resistive element 51 included in them) of the magneto-electric conversion unit 62a arranged on the arm 24c₁ of the conductor 24 and each resistance value varies. For example, the resistance values of the resistive sides Ra, Rc increase (or decrease) and the resistance values of the resistive sides Rb, Rd decrease (or increase), thereby disrupting the resistance balance of the resistive sides Ra to Rd. Herein, the magnetic field intensity can be detected by inputting the drive voltage into the drive terminal VDD relative to the ground terminal GND and detecting the differential voltage output between the output terminals Npa1, Npa2. In this way, the horizontal magnetic field generated on the upper surface of the arm 24c₁ can be detected.

The magneto-electric conversion unit 62b is also configured similarly to the magneto-electric conversion unit 62a and includes four resistive sides Re to Rh constituting the Wheatstone bridge circuit. Each of the resistive sides Re to Rh is formed of the above-described plurality of magneto-resistive elements 51 connected in series. Herein, in four resistive sides Re to Rh, the resistive side Re and the resistive side Rf are connected in series to form the output terminal Npb1 between them, the resistive side Rg and the resistive side Rh are connected in series to form the output terminal Npb2 between them, the resistive side Re and the resistive side Rf and the resistive side Rg and the resistive side Rh are connected in parallel to form the drive terminal VDD between the resistive side Rf and the resistive side Rg as well as to form the ground terminal GND between the resistive side Re and the resistive side Rh.

It should be noted that, in the current sensor 110 according to the present embodiment, the magnetic field detection directions from the resistive side Re to the resistive side Rh (that is, the magnetic sensing direction) is a single-axial direction parallel to the upper surface of the conductor 24 (the longitudinal direction in FIG. 1A), similarly to that from the resistive side Ra to the resistive side Rd. The magnetic field detection directions of the resistive side Re and the resistive side Rg (the magneto-resistive element 51 forming each of them) is identical to each other (indicated with hollow arrows in FIG. 3) and are upward (or downward) in the longitudinal direction in FIG. 1A in the present example. The magnetic field detection directions of the resistive side Rf and the resistive side Rh (the magneto-resistive elements 51 forming each of them) are also identical to each other (indicated with filled arrows in FIG. 3) and are downward (or upward) in the longitudinal direction in FIG. 1A the present example. The magnetic field detection direction of the resistive side Re and the resistive side Rg is opposite to the magnetic field detection direction of the resistive side Rf and the resistive side Rh.

The magneto-electric conversion unit 62b is arranged on the arm 24c₂ of the conductor

24. When the to-be-measured current flows through the conductor 24 and a magnetic field is generated around the conductor 24, a magnetic field in the longitudinal direction is applied to the resistive sides Re to Rh (the magneto-resistive elements 51 included in them) of the magneto-electric conversion unit 62b arranged on the arm 24c₂ of the conductor 24 and each resistance value varies. For example, the resistance values of the resistive sides Re, Rg increase (or decrease) and the resistance values of the resistive sides Rf, Rh decrease (or increase), thereby disrupting the resistance balance of the resistive sides Re to Rh. Herein, the magnetic field intensity can be detected by inputting the drive voltage into the drive terminal VDD relative to the ground terminal GND and detecting the differential voltage output between the output terminals Npb1, Npb2.

It should be noted that, as described above, the two magneto-electric conversion units 62a, 62b can be arranged on the two arms 24c₁, 24c₂ of the conductor 24, respectively. In this way, the disturbance magnetic field can be canceled. It should be noted that only one of the two magneto-electric conversion units 62a, 62b may be arranged on the conductor 24 (the two arms 24c₁, 24c₂, the joining portion 24c₃, or the like). The two magneto-electric conversion units 62a, 62b are arranged on one side and the

other side of the substrate 61, respectively, such that they are separated in the longitudinal direction (the width direction of the arms 24c₁, 24c₂) and each drive terminal VDD, ground terminal GND, and output terminals Npa1, Npa2, Npb1, Npb2 may be connected to the electrode pads 63_{#1} to 63_{#6} on the substrate 61.

The plurality of electrode pads 63_{#1} to 63_{#6} may be pads that are disposed on the substrate 61, hard-wired to the power supply terminals and the output terminals of the two magneto-electric conversion units 62a, 62b, and input the drive voltage from outside to the power supply terminal and also output the differential voltage from the output terminal to the outside. The electrode pads 63_{#1} to 63_{#6} are made of a conductive metal such as gold, copper, or aluminum, are formed on the substrate 61, and are arranged in the longitudinal direction on one side of the lateral direction (the left side in FIG. 1A and FIG. 2A) in the region between the two magneto-electric conversion units 62a, 62b with respect to the longitudinal direction. It should be noted that the plurality of electrode pads 63_{#1} to 63_{#6} are arranged linearly in the longitudinal direction, but each of them may somewhat offset in the lateral direction.

Each of the plurality of electrode pads 63_{#1} to 63_{#6} may be connected to any of the drive terminal VDD and the ground terminal GND of the two magneto-electric conversion units 62a, 62b, the two output terminals Npa1, Npa2 of the magneto-electric conversion unit 62a, and the two output terminals Npb1, Npb2 of the magneto-electric conversion unit 62b. In other words, the included electrode pads are each connected to the drive terminal VDD and the ground terminal

GND, the output terminals Npa1, Npa2, and the output terminals Npb1, Npb2. The details of the arrangement of the plurality of electrode pads 63_{#1} to 63_{#6} will be described below.

The plurality of dummy pads 64_{#1} to 64_{#6} are the test pads for signal input, which are disposed on the substrate 61, hard-wired to the power supply terminals and output terminals of the two magneto-electric conversion units 62a, 62b, and used for testing the characteristics of the magneto-electric conversion units 62a, 62b (the resistive sides Ra to Rh included in them or the magneto-resistive element 51 constituting them). The dummy pads 64_{#1} to 64_{#6} are made of a conductive metal such as gold, copper, or aluminum, are formed on the substrate 61, and are arranged in the longitudinal direction on the other side of the lateral direction (the right side in FIG. 1A and FIG. 2A) in the region between the two magneto-electric conversion units 62a, 62b with respect to the longitudinal direction. It should be noted that the plurality of dummy pads 64_{#1} to 64_{#6} are arranged linearly in the longitudinal direction, but each of them may somewhat offset in the lateral direction.

Each of the plurality of dummy pad 64_{#1} to 64_{#6} is connected to any of the drive terminal VDD and the ground terminal GND of the two magneto-electric conversion units 62a, 62b, the two output terminals Npa1, Npa2 of the magneto-electric conversion unit 62a, and the two output terminals Npb1, Npb2 of the magneto-electric conversion unit 62b. In other words, the included dummy pads are each connected to the drive terminal VDD and the ground terminal GND, the output terminals Npa1, Npa2, and the output terminals Npb1, Npb2. The plurality of dummy pads 64_{#1} to 64_{#6} can be arranged similarly to the plurality of electrode pads 63_{#1} to 63_{#6}.

The plurality of electrode pads 63_{#1} to 63_{#6} and the plurality of dummy pads 64_{#1} to 64_{#6} are arranged on the substrate 61 on one side and the other side, respectively, in the lateral direction between the two magneto-electric conversion units 62a, 62b separated in the longitudinal direction. In this way, the two magneto-electric conversion units 62a, 62b, the plurality of electrode pads 63_{#1} to 63_{#6}, and the plurality of dummy pads 64_{#1} to 64_{#6} can be arranged within a small area on the substrate 61.

It should be noted that the plurality of dummy pads 64_{#1} to 64_{#6} may be each disposed opposite to the plurality of electrode pads 63_{#1} to 63_{#6} in the lateral direction. In other words, the plurality of dummy pads 64_{#1} to 64_{#6} may be each disposed opposite to the electrode pads in the lateral direction, among the plurality of electrode pads 63_{#1} to 63_{#6}, connected to the same terminal among the six terminals of the two magneto-electric conversion units 62a, 62b. Herein, the dummy pad connected to the ground terminal GND of the two magneto-electric conversion units 62a, 62b among the plurality of dummy pads 64_{#1} to 64_{#6} may be connected to the electrode pad connected to the ground terminal GND of the two magneto-electric conversion units 62a, 62b among the plurality of electrode pads 63_{#1} to 63_{#6}. It is noted that the dummy pads connected to the drive terminal VDD and the output terminals Npa1, Npa2, Npb1, Npb2 of the two magneto-electric conversion units 62a, 62b among the plurality of dummy pads 64_{#1} to 64_{#6} are not connected to the electrode pads connected to the drive terminal VDD and the output terminals Npa1, Npa2, Npb1, Npb2 of the two magneto-electric conversion units 62a, 62b among the plurality of electrode pads 63_{#1} to 63_{#6}.

The magnetic sensor 60 is arranged on the curved portion 24c of the conductor 24. In this way, the two magneto-electric conversion units 62a, 62b are arranged on the two arms 24c₁, 24c₂ of the curved portion 24c, respectively, and the plurality of electrode pads 63_{#1} to 63_{#6} on the substrate 61 connected to their drive terminal VDD, the ground terminal GND, and the output terminals Npa1, Npa2, Npb1, Npb2 are connected to the device terminal 17 via wire bonding. In this way, the drive voltage can be applied to the two magneto-electric conversion units 62a, 62b via the device terminal 17 and each differential voltage can be output.

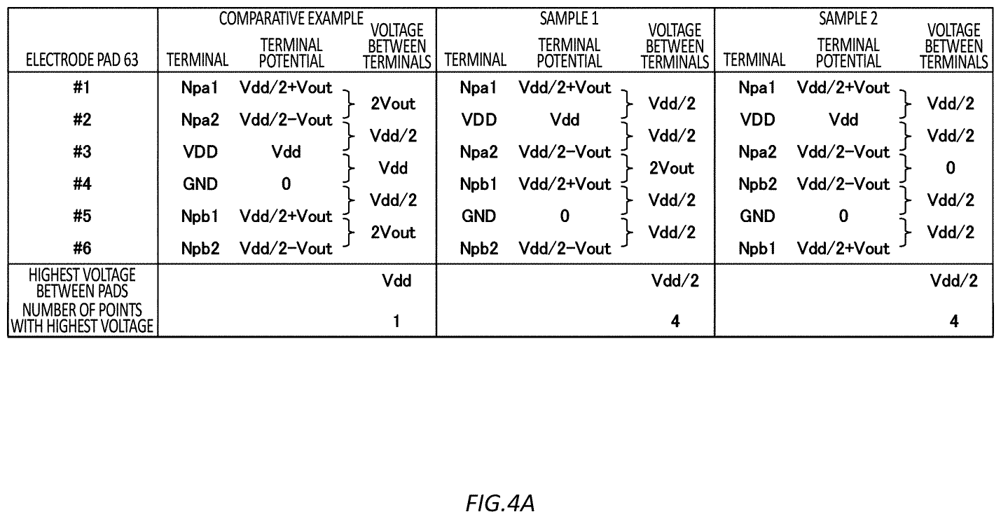

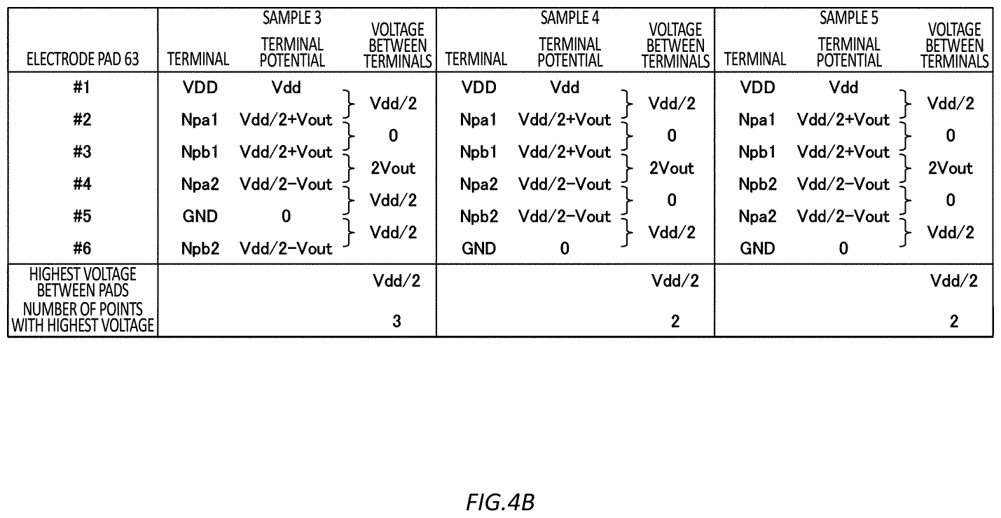

FIG. 4A and FIG. 4B illustrate an example (a comparative example, samples 1 to 5) of a combination of a connection between the plurality of electrode pads 63_{#1} to 63_{#6} and the six terminals of the magnetic sensor 60 (the drive terminal VDD, the ground terminal GND, and the output terminals Npa1, Npa2, Npb1, Npb2). In the comparative example, the electrode pads 63_{#1} to 63_{#6} are each connected to the output terminal Npa1 (terminal potential Vdd/2+Vout), the output terminal Npa2 (Vdd/2−Vout), the drive terminal VDD (Vdd), the ground terminal GND (zero), the output terminal Npb1 (Vdd/2+Vout), and the output terminal Npb2 (Vdd/2−Vout). Herein, it is assumed that the drive voltage between the power supply terminals (the drive terminal VDD and the ground terminal GND) is Vdd (each terminal potential is Vdd and zero), the resistance values of the resistive sides Ra, Rb, the resistance values of the resistive sides Rc, Rd, the resistance values of the resistive sides Re, Rf, and the resistance values of the resistive side Rg, Rh are equal, and the magnetic field applied to the magnetic sensor 60 (the magneto-electric conversion units 62a, 62b) generates differential voltage 2Vout between the output terminals Npa1, Npa2 of the magneto-electric conversion unit 62a and generates differential voltage 2Vout between the output terminals Npb1, Npb2 of the magneto-electric conversion unit 62b. It should be noted that Vout<<Vdd.

When the potential difference occurs between the plurality of electrode pads 63_{#1} to 63_{#6}, ion migration progresses, in other words, the electrode material is eluted and causes the short-circuit of the adjacent electrode pads, thereby decreasing the detection sensitivity of the magnetic sensor 60. Herein, the elusion rate of the electrode material due to the ion migration is proportional to the amount of current I flowing between the electrode pads due to a redox reaction. The amount of current I is proportional to exp(cV) according to the Butler-Volmer equation. Herein, V is the voltage between adjacent electrode pads and c is a constant. Therefore, the drive terminal VDD and the ground terminal GND, the output terminals Npa1, Npa2, and the output terminals Npb1, Npb2 of the magnetic sensor 60 are preferably connected to the plurality of electrode pads 63_{#1} to 63_{#6} so that the potential difference between the adjacent electrode pads is small.

In the comparative example, as described above, when the six terminals of the magnetic sensor (the drive terminal VDD, the ground terminal GND, and the output terminals Npa1, Npa2, Npb1, Npb2) are connected to the plurality of electrode pads 63_{#1} to 63_{#6}, the potential difference (that is, the voltage) between the adjacent electrode pads 63_{#1}, 63_{#2} is 2Vout, the voltage between the electrode pads 63_{#2}, 63_{#3} is Vdd/2, the voltage between the electrode pads 63_{#3}, 63_{#4} is Vdd, the voltage between the electrode pads 63_{#4}, 63_{#5} is Vdd/2, and the voltage between the electrode pads 63_{#5}, 63_{#6} is 2Vout, meaning that the highest voltage between the electrode pads is as high as Vdd.

In sample 1, the electrode pads 63_{#1} to 63_{#6} are each connected to the output terminal Npa1 (the terminal potential Vdd/2+Vout), the drive terminal VDD (Vdd), the output terminal Npa2 (Vdd/2−Vout), the output terminal Npb1 (Vdd/2+Vout), the ground terminal GND (zero) and the output terminal Npb2 (Vdd/2−Vout). In this case, the potential difference (that is, the voltage) between the electrode pads 63_{#1}, 63_{#2} is Vdd/2, the voltage between the electrode pads 63_{#2}, 63_{#3} is Vdd/2, the voltage between the electrode pads 63_{#3}, 63_{#4} is 2Vout, the voltage between the electrode pads 63_{#4}, 63_{#5} is Vdd/2, and the voltage between the electrode pads 63_{#5}, 63_{#6} is Vdd/2, meaning that the highest voltage between the electrode pads is Vdd/2, which is half of that in the comparative example, but the number of points providing the highest voltage increases to four, compared to one in the comparative example.

In sample 2, the electrode pads 63_{#1} to 63_{#6} are each connected to the output terminal Npa1 (the terminal potential Vdd/2+Vout), the drive terminal VDD (Vdd), the output terminal Npa2 (Vdd/2−Vout), the output terminal Npb2 (Vdd/2−Vout), the ground terminal GND (zero), and the output terminal Npb1 (Vdd/2+Vout). In this case, the potential difference (that is, the voltage) between the electrode pads 63_{#1}, 63_{#2} is Vdd/2, the voltage between the electrode pads 63_{#2}, 63_{#3} is Vdd/2, the voltage between the electrode pads 63_{#3}, 63_{#4} is zero, the voltage between the electrode pads 63_{#4}, 63_{#5} is Vdd/2, and the voltage between the electrode pads 63_{#5}, 63_{#6} is Vdd/2, meaning that the highest voltage between the electrode pads is Vdd/2, which is half of that in the comparative example, but the number of points providing the highest voltage increases to four, compared to one in the comparative example.

In sample 3, the electrode pads 63_{#1} to 63_{#6} are each connected to the drive terminal VDD (the terminal potential Vdd), the output terminal Npa1 (Vdd/2+Vout), the output terminal Npb1 (Vdd/2+Vout), the output terminal Npa2 (Vdd/2−Vout), the ground terminal GND (zero), and the output terminal Npb2 (Vdd/2−Vout). In this case, the potential difference (that is, the voltage) between the electrode pads 63_{#1}, 63_{#2} is Vdd/2, the voltage between the electrode pads 63_{#2}, 63_{#3} is zero, the voltage between the electrode pads 63_{#3}, 63_{#4} is 2Vout, the voltage between the electrode pads 63_{#4}, 63_{#5} is Vdd/2, and the voltage between the electrode pads 63_{#5}, 63_{#6} is Vdd/2, meaning that the highest voltage between the electrode pads is Vdd/2, which is half of that in the comparative example, but the number of points providing the highest voltage increases to three, compared to one in the comparative example. It is noted that the number of points providing the highest voltage decreases to three, compared to four in samples 1 and 2.

In sample 4, the electrode pads 63_{#1} to 63_{#6} are each connected to the drive terminal

VDD (the terminal potential Vdd), the output terminal Npa1 (Vdd/2+Vout), the output terminal Npb1 (Vdd/2+Vout), the output terminal Npa2 (Vdd/2−Vout), the output terminal Npb2 (Vdd/2−Vout), and the ground terminal GND (zero). In this case, the potential difference (that is, the voltage) between the electrode pads 63_{#1}, 63_{#2} is Vdd/2, the voltage between the electrode pads 63_{#2}, 63_{#3} is zero, the voltage between the electrode pads 63_{#3}, 63_{#4} is 2Vout, the voltage between the electrode pads 63_{#4}, 63_{#5} is zero, and the voltage between the electrode pads 63_{#5}, 63_{#6} is Vdd/2, meaning that the highest voltage between the electrode pads is Vdd/2, which is half of that in the comparative example, but the number of points providing the highest voltage increases to two, compared to one in the comparative example. It is noted that the number of points providing the highest voltage decreases to two, compared to four in samples 1 and 2.

Based on the consideration of samples 1 to 4, since the drive terminal VDD (terminal

potential Vdd) provides the highest potential and the ground terminal GND (zero) provides the lowest potential, the highest voltage between the pads can be smaller (in the present example, about a half) by arranging, between the electrode pads connected to these terminals, at least one electrode pads among the electrode pad connected to the output terminal Npa1 (Vdd/2+Vout), the electrode pad connected to the output terminal Npa2 (Vdd/2−Vout), the electrode pad connected to the output terminal Npb1 (Vdd/2+Vout), and the electrode pad connected to the output terminal Npb2 (Vdd/2−Vout). In particular, the number of points providing the highest voltage is preferably small because this results in a smaller number of points where the migration occurs, and sample 4 among samples 1 to 4 is appropriate.

Because the substrate 61 of the magnetic sensor 60 is arranged on the conductor 24, the to-be-measured current flowing through the substrate 61 heats the substrate 61, which heats the conductor 24. In this way, thermo-electromotive force is generated on the joint surface of the electrode pads 63_{#1} to 63_{#6} and the wire bonding and inside the Wheatstone bridge, causing a concern about the decrease in the precision due to the offset. It should be noted that the thermo-electromotive force is a phenomenon in which, when the joint interface is placed at a certain temperature or when the temperatures on both ends of the material are different, a potential difference occurs between them.

The electrode pads each connected to the two output terminals Npa1, Npa2 of the magneto-electric conversion unit 62a are preferably arranged inward or outward relative to the electrode pads each connected to the two output terminals Npb1, Npb2 of the magneto-electric conversion unit 62b. In this way, the electrode pads each connected to the two output terminals Npa1, Npa2 of the magneto-electric conversion unit 62a are each separated from the two arms 24c₁, 24c₂ of the conductor 24 by the same distances or approximately the same distances as well as the electrode pads each connected to the two output terminals Npb1, Npb2 of the magneto-electric conversion unit 62b are each separated from the two arms 24c₁, 24c₂ of the conductor 24 by the same distances or approximately the same distances, so that they are equally heated due to the heated conductor 24, resulting in a smaller temperature difference, which can suppress the offset due to the thermo-electromotive force.

Further preferably, with the axis of symmetry L passing through the center with respect to the longitudinal direction of the substrate 61 as the reference, the electrode pads each connected to the two output terminals Npa1, Npa2 of the magneto-electric conversion unit 62a are arranged at the symmetrical positions with respect to the longitudinal direction and furthermore the electrode pads each connected to the two output terminals Npb1, Npb2 of the magneto-electric conversion unit 62b are arranged at the symmetrical positions with respect to the longitudinal direction. By arranging the magnetic sensor 60 on the conductor 24 such that the axis of symmetry L of the substrate 61 overlaps with the center line of the conductor 24, the electrode pads each connected to the two output terminals Npa1, Npa2 of the magneto-electric conversion unit 62a are each separated from the two arms 24c₁, 24c₂ of the conductor 24 by the same distances or approximately the same distances, as well as the electrode pads each connected to the two output terminals Npb1, Npb2 of the magneto-electric conversion unit 62b are each separated from the two arms 24c₁, 24c₂ of the conductor 24 by the same distances or approximately the same distances, so that they are equally heated due to the heated conductor 24, resulting in a smaller temperature difference, which can suppress the offset due to the thermo-electromotive force.

In sample 5, the electrode pads 63_{#1} to 63_{#6} are each connected to the drive terminal VDD (the terminal potential Vdd), the output terminal Npa1 (Vdd/2+Vout), the output terminal Npb1 (Vdd/2+Vout), the output terminal Npb2 (Vdd/2−Vout), the output terminal Npa2 (Vdd/2−Vout), and the ground terminal GND (zero). In this case, the potential difference between the electrode pads 63_{#1}, 63_{#2} is Vdd/2, the potential difference between the electrode pads 63_{#2}, 63_{#3} is zero, the potential difference between the electrode pads 63_{#3}, 63_{#4} is 2Vout, the potential difference between the electrode pads 63_{#4}, 63_{#5} is zero, and the potential difference between the electrode pads 63_{#5}, 63_{#6} is Vdd/2, meaning that the highest voltage between the electrode pads is Vdd/2 similarly to sample 4 and the number of points providing the highest voltage is two. Furthermore, as described above, the two output terminals Npa1, Npa2 of the magneto-electric conversion unit 62a are each connected to the electrode pads 63_{#2}, 63_{#5} and the two output terminals Npb1, Npb2 of the magneto-electric conversion unit 62b are each connected to the electrode pads 63_{#3}, 63_{#4} so that, with the axis of symmetry L of the substrate 61 as the reference, the electrode pads each connected to the two output terminals Npa1, Npa2 of the magneto-electric conversion unit 62a are arranged symmetrically and the electrode pads each connected to the two output terminals Npb1, Npb2 of the magneto-electric conversion unit 62b are arranged symmetrically. In this way, the offset due to the thermo-electromotive force can be suppressed.

It should be noted that the plurality of dummy pads 64_{#1} to 64_{#6} are also disposed on the substrate 61 according to a similar principle to that of the plurality of electrode pads 63_{#1} to 63_{#6} and can suppress the migration and offset.

If the resistance balance of the wiring connecting the plurality of electrode pads 63_{#1} to 63_{#6} and the six terminals of the magnetic sensor is disrupted, there is a concern that the midpoint potentials (the potentials at the output terminals Npa1, Npa2, Npb1, Npb2) of the Wheatstone bridge circuit included in each of the magneto-electric conversion units 62a, 62b shift and offset occurs in the differential voltage output from the output terminals Npa1, Npa2, Npb1, Npb2 (which results in the shift of the bias point of a differential amplifier circuit connected to the output terminal), and the detection precision of the magnetic sensor 60 decreases. Therefore, in particular, it is preferable that the resistances of the wiring connecting the plurality of electrode pads 63_{#1} to 63_{#6} to the drive terminal VDD and the ground terminal GND of the magnetic sensor are matched.

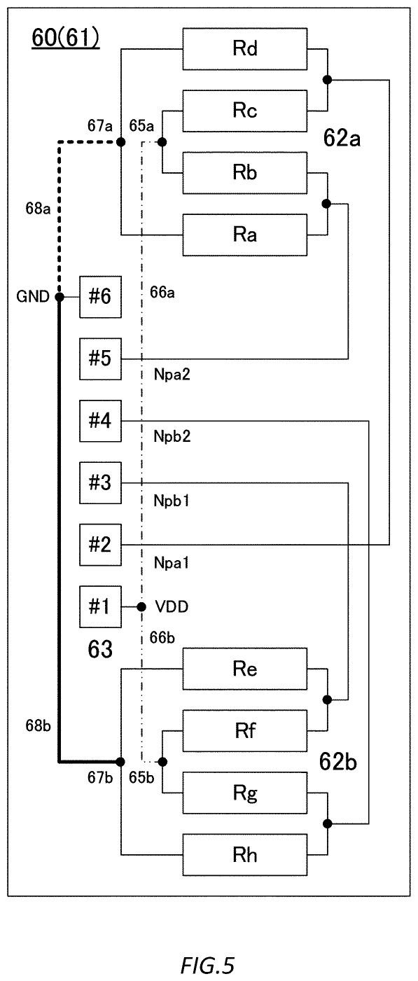

FIG. 5 illustrates an example of laying the wiring in sample 5 (see FIG. 4B) of a combination of a connection between the plurality of electrode pads 63_{#1} to 63_{#6} and the six terminals (the drive terminal VDD, the ground terminal GND, and the output terminals Npa1, Npa2, Npb1, Npb2) of the magnetic sensor 60. In sample 5, the electrode pads 63_{#1} to 63_{#6} are each connected to the drive terminal VDD, the output terminal Npa1, the output terminal Npb1, the output terminal Npb2, the output terminal Npa2, and the ground terminal GND. It should be noted that the wirings are connected at an intersection point indicated with a black dot and are separated in the up and down direction via the insulating layer, for example, at an intersection point without the black dot.

Herein, the wiring 66a extending from the drive terminal of the magneto-electric conversion unit 62a (the connection point 65a of the resistive sides Rb, Rc) to the electrode pad 63_{#1} (indicated with the single-dot dash line in the figure) is longer and has a larger cross-sectional area than the wiring 66b extending from the drive terminal of the magneto-electric conversion unit 62b (the connection point 65b of the resistive sides Rf, Rg) to the electrode pad 63_{#1} (indicated with the double-dot dash line in the figure). Alternatively, the wiring 66a may also be shorter and have a smaller cross-sectional area than the wiring 66b. More preferably, the wiring 66a and the wiring 66b have the same or approximately the same product of the length and the cross-sectional area. In other words, the wiring 66a extending from the drive terminal of the magneto-electric conversion unit 62a (the connection point 65a of the resistive sides Rb, Rc) to the electrode pad 63_{#1} has the resistance value equal to or approximately equal to that of the wiring 66b extending from the drive terminal of the magneto-electric conversion unit 62b (the connection point 65b of the resistive sides Rf, Rg) to the electrode pad 63_{#1}. Furthermore, the wiring 68a extending from the ground terminal (the connection point

67a of the resistive sides Ra, Rd) of the magneto-electric conversion unit 62a to the electrode pad 63_{#6} (indicated with the thick dotted line in the figure) is shorter and has a smaller cross-sectional area than the wiring 68b extending from the ground terminal (the connection point 67b of the resistive sides Re, Rh) of the magneto-electric conversion unit 62b to the electrode pad 63_{#6} (indicated with a thick line in the figure). Alternatively, the wiring 68a may be longer and have a larger cross-sectional area than the wiring 68b. In other words, the wiring 68a extending from the ground terminal (the connection point 67a of the resistive sides Ra, Rd) of the magneto-electric conversion unit 62a to the electrode pad 63_{#6} has the resistance value equal to or approximately equal to that of the wiring 68b extending from the ground terminal (the connection point 67b of the resistive sides Re, Rh) of the magneto-electric conversion unit 62b to the electrode pad 63_{#6}.

In this way, the operating point of the differential voltage output between the output terminals Npa1, Npa2 is aligned with that of the differential voltage output from the output terminals Npb1, Npb2, which can maintain the detection precision of the magnetic sensor 60.

There is a concern that connecting the plurality of electrode pads 63_{#1} to 63_{#6} to the six terminals (the drive terminal VDD, the ground terminal GND, and the output terminals Npa1, Npa2, Npb1, Npb2) of the magnetic sensor 60 forms a wiring loop and magnetic flux passing inside the loop generates an induced electromotive force on the wiring, decreasing the detection precision of the magnetic sensor 60. Therefore it is preferable to lay the wiring such that the wiring loop is not formed.

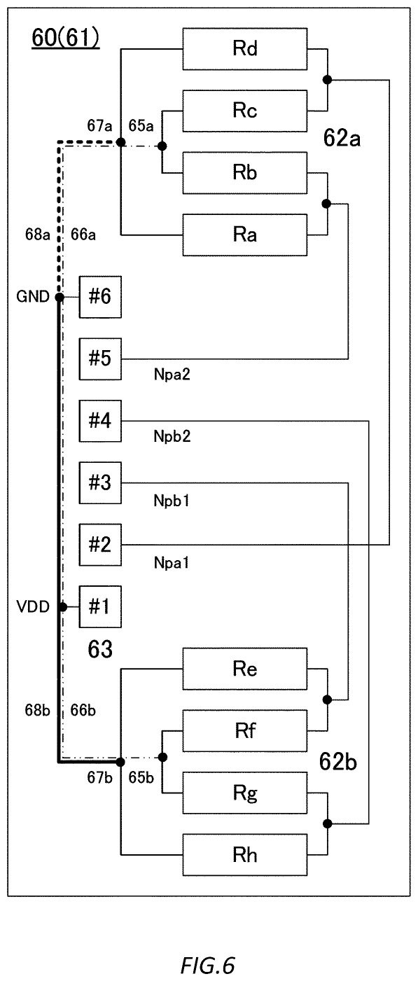

FIG. 6 illustrates another example of laying the wiring in sample 5 (see FIG. 4B) of a combination of a connection between the plurality of electrode pads 63_{#1} to 63_{#6} and the six terminals (the drive terminal VDD, the ground terminal GND, and the output terminals Npa1, Npa2, Npb1, Npb2) of the magnetic sensor 60. In sample 5, the electrode pads 63_{#1} to 63_{#6} are each connected to the drive terminal VDD, the output terminal Npa1, the output terminal Npb1, the output terminal Npb2, the output terminal Npa2, and the ground terminal GND. It should be noted that the wirings is connected at the intersection point indicated with a black dot and are separated in the up and down direction via the insulating layer, for example, at the intersection points without the black dot.

The wiring pair including the wiring 66a extending from the drive terminal (the connection point 65a of the resistive sides Rb, Rc) of the magneto-electric conversion unit 62a to the electrode pad 63_{#1} (indicated with the single-dot dash line in the figure) and the wiring 66b extending from the drive terminal (the connection point 65b of the resistive sides Rf, Rg) of the magneto-electric conversion unit 62b to the electrode pad 63_{#1} (indicated with the double-dot dash line in the figure) is disposed on the substrate 61 such that in a top view it at least partially overlaps with the wiring pair including the wiring 68a extending from the ground terminal of the magneto-electric conversion unit 62a (the connection point 67a of the resistive sides Ra, Rd) to the electrode pad 63_{#6} (indicated with the thick dotted line in the figure) and the wiring 68b extending from the ground terminal (the connection point 67b of the resistive sides Re, Rh) of the magneto-electric conversion unit 62b to the electrode pad 63_{#6} (indicated with the thick line in the figure). In the present example, the wiring pairs 68a, 68b entirely overlap with the wiring pairs 66a, 66b. It should be noted that, for convenience of illustration, FIG. 6 illustrates the two wiring pairs (66a, 66b, 68a, 68b) slightly shifted. In this way, the two wiring pairs do not form the wiring loop, which can suppress the generation of the induced electromotive force on the wiring and maintain the detection precision of the magnetic sensor 60.

It should be noted that the wiring connecting the six terminals of the magnetic sensor 60

to the plurality of dummy pads 64_{#1} to 64_{#6} can also be laid on the substrate 61 according to the principle similar to that of the wiring connected to the plurality of electrode pads 63_{#1} to 63_{#6}.

The method for manufacturing the current sensor 110 will be described.

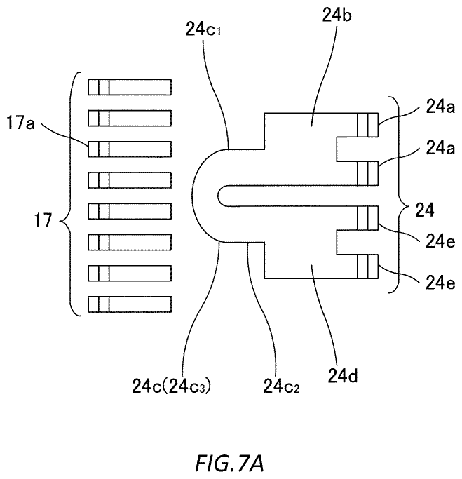

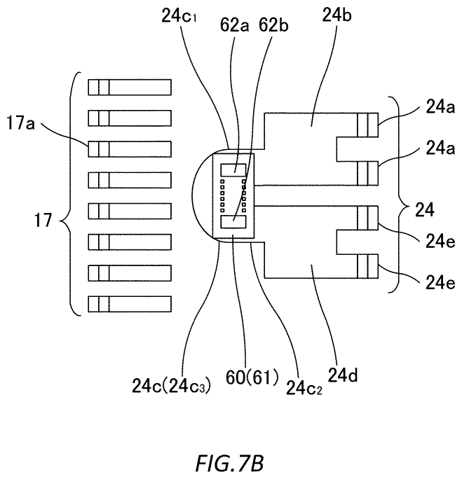

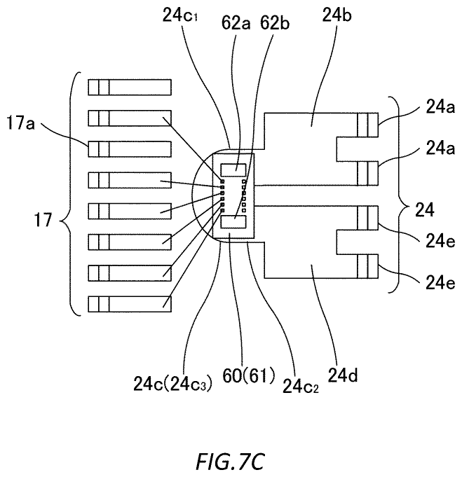

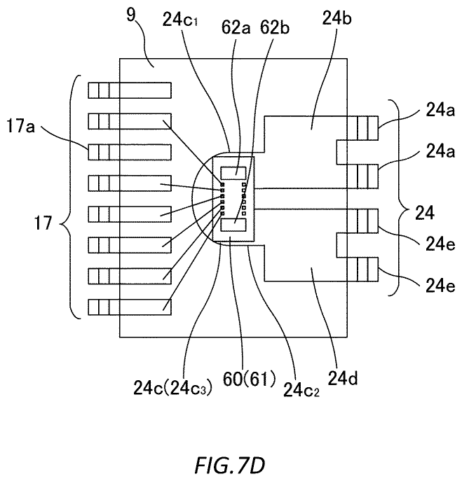

As illustrated in FIG. 7A, at first, one piece of metal board undergoes a stamping process to form the pattern of the plurality of device terminals 17 and the conductor 24. This pattern allows the plurality of device terminals 17 and the conductor 24 to be included within a rectangular-shaped frame (not shown), with their terminal portions coupled inside.

Then, the pattern undergoes a step process to provide steps in the plurality of device terminals 17 and the conductor 24. As a result, with respect to the frame and its terminal portions coupled to the frame, the inner part of the pattern is raised.

As illustrated in FIG. 7B, the magnetic sensor 60 is then installed. Herein, two magneto-electric conversion units 62a, 62b are arranged on the arms 24c₁, 24c₂ of the conductor 24, respectively.

As illustrated in FIG. 7C, the magnetic sensor 60 and the plurality of device terminals 17 are then connected with wire bonding.

As illustrated in FIG. 7D, the pattern is then molded such that the frame and the plurality

of device terminals 17 and the terminal portions of the conductor 24 coupled to the frame are left. In this way, the package 9 is formed and the magnetic sensor 60 and the inner part of the pattern are encapsulated inside the package 9.

Finally, the frame exposed on the outside of the package 9 is cut off from the pattern. In this way, the plurality of device terminals 17 and the conductor 24 are separated from each other and the current sensor 110 is completed.

It should be noted that the current sensor 110 may further include a signal processing

device that processes the output signal of the magnetic sensor 60 and calculates the amount of the to-be-measured current flowing through the conductor 24 and the base supporting the signal processing device (neither is shown). The signal processing device may incorporate a memory, a sensitivity correction circuit, an offset correction circuit which corrects an offset of an output, an amplifying circuit which amplifies the output signal from the magnetic sensor 60, and a temperature correction circuit which corrects the output according to temperature. The signal processing device may be supported on the base and be connected to the magnetic sensor 60 (the plurality of electrode pads 63_{#1} to 63_{#6}) and the plurality of device terminals 17 via wire bonding. Alternatively, the signal processing device may incorporate the substrate 61 having the magnetic sensor 60, use the electrode pads 63_{#1} to 63_{#6} as the input/output terminals of the signal processing device, and be connected to the plurality of device terminals 17 via wire bonding. In this way, the signal processing device outputs the calculated result of the amount of the to-be-measured current flowing through the conductor 24 via the plurality of device terminals 17.

The magnetic sensor 60 according to the present embodiment includes the substrate 61, the plurality of magneto-resistive elements 51 disposed on the substrate 61, wherein a part of the plurality of magneto-resistive element 51 is assembled into a Wheatstone bridge circuit to form the magneto-electric conversion unit 62a and another part of the plurality of magneto-resistive elements 51 is assembled into a Wheatstone bridge circuit to form the magneto-electric conversion unit 62b, and the plurality of electrode pads 63_{#1} to 63_{#6} disposed on the substrate 61, including a first electrode pad connected to the drive terminal VDD of the magneto-electric conversion units 62a, 62b, a second electrode pad connected to the ground terminal GND of the magneto-electric conversion units 62a, 62b, a third electrode pad and a fourth electrode pad connected to the two output terminals Npa1, Npa2 of the magneto-electric conversion unit 62a, respectively, and a fifth electrode pad and a sixth electrode pad connected to the two output terminals Npb1, Npb2 of the magneto-electric conversion unit 62b, respectively, wherein at least one electrode pad among the third electrode pad to the sixth electrode pad is arranged between the first electrode pad and the second electrode pad in the direction in which the first electrode pad and the second electrode pad are separated. In this way, at least one electrode pad among the third to sixth electrode pads is arranged between the first electrode pad second electrode pad where the highest potential difference occurs, which results in the voltage diffidence between the adjacent electrode pads being smaller than the highest voltage, which can suppress the migration of the electrode pad.

The current sensor 110 according to the present embodiment includes the conductor 24 through which the to-be-measured current flows, the magnetic sensor 60 arranged on the conductor 24, and the plurality of device terminals 17 each connected to the first electrode pad to the sixth electrode pad of the magnetic sensor 60. In this way, using the magnetic sensor 60 where the migration of the electrode pad is suppressed, the current sensor 110 with high credibility can be provided.

It should be noted that the magnetic sensor 60 was assumed to include the two magneto-electric conversion units 62a, 62b but may instead include only one of them.

It should be noted that, in the current sensor 110 according to the present embodiment, the plurality of electrode pads 63_{#1} to 63_{#6} of the magnetic sensor 60 were assumed to be connected to the device terminal 17 via wire bonding but instead the plurality of dummy pads 64_{#1} to 64_{#6} may be connected to the device terminal 17 via wire bonding. In this case, the plurality of electrode pads 63_{#1} to 63_{#6} may be used as the test pad for signal input for testing the characteristics of the magneto-electric conversion units 62a, 62b (the resistive sides Ra to Rh included in them or the magneto-resistive element 51 constituting them).

It should be noted that, with the magnetic field detection direction of the resistive sides Ra to Rh (the magneto-resistive element 51) included in the two magneto-electric conversion units 62a, 62b of the magnetic sensor 60 (that is, the magnetic sensing direction) being in the direction perpendicular to the upper surface of the conductor 24, one of the two magneto-electric conversion units 62a, 62b may be arranged in a gap region surrounded by the curved portion 24c of the conductor 24. In this way, the magnetic sensor 60 can detect the perpendicular magnetic field (in the case of the present example, the magnetic field in the height direction in FIG. 1A). In addition, the other of the two magneto-electric conversion units 62a, 62b may be arranged in the vicinity of the outside of one of the two arms 24c₁, 24c₂ of the conductor 24. In this way, the disturbance magnetic field can be canceled.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A current sensor comprising a conductor through which a to-be-measured current flows and a magnetic sensor arranged on the conductor, wherein the magnetic sensor includes:
a substrate;
a plurality of magneto-resistive elements disposed on the substrate, wherein a part of the plurality of magneto-resistive elements is assembled into a Wheatstone bridge circuit to form a first sensor, and another part of the plurality of magneto-resistive elements is assembled into a Wheatstone bridge circuit to form a second sensor; and
a plurality of electrode pads disposed on the substrate, including a first electrode pad connected to a drive terminal of the first sensor and the second sensor, a second electrode pad connected to a ground terminal of the first sensor and the second sensor, a third electrode pad and a fourth electrode pad each connected to two output terminals of the first sensor, and a fifth electrode pad and a sixth electrode pad each connected to two output terminals of the second sensor, wherein at least one electrode pad among the third electrode pad to the sixth electrode pad is arranged between the first electrode pad and the second electrode pad in a first direction in which the first electrode pad and the second electrode pad are separated.

2. The current sensor according to claim 1, wherein the third electrode pad and the fourth electrode pad are arranged inward or outward relative to the fifth electrode pad and the sixth electrode pad with respect to the first direction.

3. The current sensor according to claim 2, wherein the substrate has an axis of symmetry passing a center with respect to the first direction,
the third electrode pad and the fourth electrode pad are arranged at symmetrical positions with respect to the first direction with the axis of symmetry as a reference, and
the fifth electrode pad and the sixth electrode pad are arranged at symmetrical positions with respect to the first direction with the axis of symmetry as a reference.

4. The current sensor according to claim 1, wherein wiring extending from a drive terminal of the first sensor to the first electrode pad is longer and has a larger cross-sectional area or is shorter and has a smaller cross-sectional area than wiring extending from a drive terminal of the second sensor to the first electrode pad.

5. The current sensor according to claim 1, wherein wiring extending from a drive terminal of the first sensor to the first electrode pad has a resistance approximately equal to that of wiring extending from a drive terminal of the second sensor to the first electrode pad.

6. The current sensor according to claim 1, wherein wiring extending from a ground terminal of the first sensor to the second electrode pad is shorter and has a smaller cross-sectional area or is longer and has a larger cross-sectional area than wiring extending from a ground terminal of the second sensor to the second electrode pad.

7. The current sensor according to claim 1, wherein wiring extending from a ground terminal of the first sensor to the second electrode pad has a resistance approximately equal to that of wiring extending from a ground terminal of the second sensor to the second electrode pad.

8. The current sensor according to claim 1, wherein, in a top view, a first wiring pair including wiring extending from a drive terminal of the first sensor to the first electrode pad and wiring extending from a drive terminal of the second sensor to the first electrode pad at least partially overlaps with a second wiring pair including wiring extending from a ground terminal of the first sensor to the second electrode pad and wiring extending from a ground terminal of the second sensor to the second electrode pad.

9. The current sensor according to claim 1, wherein the first sensor and the second sensor are arranged on one side and another side on the substrate in the first direction, respectively, and
the first electrode pad to the sixth electrode pad are arranged on one side in a direction intersecting with the first direction, in a region between the first sensor and the second sensor on the substrate.

10. The current sensor according to claim 9, wherein the conductor has a first arm and a second arm separated in the first direction, a to-be-measured current is input into one arm among the first arm and the second arm, and the to-be-measured current is output from another arm, and
the first sensor and the second sensor are arranged on the first arm and the second arm, respectively.

11. The current sensor according to claim 10, wherein the conductor has a joining portion that physically joins the first arm and the second arm, and
the first arm and the second arm extend on a same side with respect to the joining portion.

12. The current sensor according to claim 11, wherein the first sensor and the second sensor are arranged on one side and another side on the substrate in the first direction, respectively, and
the first electrode pad to the sixth electrode pad are arranged on one side in a direction intersecting with the first direction, in a region between the first sensor and the second sensor on the substrate.

13. The current sensor according to claim 12, further comprising a plurality of device terminals to which the first electrode pad to the sixth electrode pad are each connected.

14. The current sensor according to claim 12, wherein the magnetic sensor further comprises a plurality of dummy pads disposed on the substrate, the plurality of dummy pads including a first dummy pad connected to a drive terminal of the first sensor and the second sensor, a second dummy pad connected to a ground terminal of the first sensor and the second sensor, a third dummy pad and a fourth dummy pad each connected to two output terminals of the first sensor, and a fifth dummy pad and a sixth dummy pad each connected to two output terminals of the second sensor, and
the first dummy pad to the sixth dummy pad are each disposed opposite to the first electrode pad to the sixth electrode pad on another side of a direction intersecting with the first direction, in a region between the first sensor and the second sensor on the substrate.

15. A current sensor comprising a conductor through which a to-be-measured current flows and a magnetic sensor arranged on the conductor, wherein the magnetic sensor includes:
a substrate;
a plurality of magneto-resistive elements disposed on the substrate, wherein a part of the plurality of magneto-resistive elements is assembled into a Wheatstone bridge circuit to form a first sensor, and another part of the plurality of magneto-resistive elements is assembled into a Wheatstone bridge circuit to form a second sensor; and
a plurality of dummy pads disposed on the substrate, including a first dummy pad connected to a drive terminal of the first sensor and the second sensor, a second dummy pad connected to a ground terminal of the first sensor and the second sensor, a third dummy pad and a fourth dummy pad each connected to two output terminals of the first sensor, and a fifth dummy pad and a sixth dummy pad each connected to two output terminals of the second sensor, wherein at least one dummy pad among the third dummy pad to the sixth dummy pad is arranged between the first dummy pad and the second dummy pad with respect to a first direction in which the first dummy pad and the second dummy pad are separated.
